(19) United States
(12) Patent Application Publication
(10) Pub. No.: US 2023/0136958 A1
(43) Pub. Date: May 4, 2023

(54) PHOTOVOLTAIC CELL DEVICE

(71) Applicants: Japan Display Inc., Tokyo (JP); OSAKA UNIVERSITY, Osaka (JP)

(72) Inventors: Shinichiro OKA, Tokyo (JP); Yasushi TOMIOKA, Tokyo (JP); Junji KOBASHI, Tokyo (JP); Hiroyuki YOSHIDA, Suita-shi (JP)

(73) Assignees: Japan Display Inc., Tokyo (JP); OSAKA UNIVERSITY, Osaka (JP)

(21) Appl. No.: 18/091,387

(22) Filed: Dec. 30, 2022

Related U.S. Application Data
(63) Continuation of application No. PCT/JP2021/024611, filed on Jun. 29, 2021.

(30) Foreign Application Priority Data
Jul. 13, 2020 (JP) 2020-119970

(51) Int. Cl. H01L 31/054; G02B 6/42

(52) U.S. Cl. CPC H01L 31/0547; H01L 31/0543; G02B 6/4214; G02B 6/4206; G02B 6/42

(57) ABSTRACT

According to one embodiment, a photovoltaic cell device includes a first optical waveguide including a first main surface, a second main surface facing the first main surface, and a first side surface, an optical element facing the second main surface, containing a cholesteric liquid crystal, and reflecting at least part of light incident on the first main surface toward the first optical waveguide, and a first photovoltaic cell facing the first side surface. The first photovoltaic cell is attached to the first side surface by a transparent first adhesive layer.

### CROSS-REFERENCE TO RELATED APPLICATIONS

This application is a Continuation Application of PCT Application No. PCT/JP2021/024611, filed Jun. 29, 2021 and based upon and claiming the benefit of priority from Japanese Patent Application No. 2020-119970, filed Jul. 13, 2020, the entire contents of all of which are incorporated herein by reference.

### FIELD

Embodiments described herein relate generally to a photovoltaic cell device.

### BACKGROUND

Recently, various types of transparent photovoltaic cells have been suggested. For example, a display device comprising a transparent dye-sensitized photovoltaic cell on the surface of the display device has been suggested. In such a photovoltaic cell device, a technique which can increase the size at low cost has been required.

### BRIEF DESCRIPTION OF THE DRAWINGS

FIG. 1 is a cross-sectional view schematically showing a photovoltaic cell device 100 according to embodiment 1.

FIG. 2 is a cross-sectional view schematically showing the structure of an optical element 3.

FIG. 3 is a plan view schematically showing the photovoltaic cell device 100.

FIG. 4 is a cross-sectional view schematically showing an example of the optical element 3.

FIG. 5 is a cross-sectional view schematically showing the optical element 3 according to modified example 1 of embodiment 1.

FIG. 6 is a plan view schematically showing the photovoltaic cell device 100 according to modified example 2.

FIG. 7 is a plan view schematically showing a photovoltaic cell device 100 according to embodiment 2.

FIG. 8 is a cross-sectional view of the photovoltaic cell device 100 along the A-B line of FIG. 7.

FIG. 9 is a cross-sectional view of the photovoltaic cell device 100 according to modified example 1 of embodiment 2.

FIG. 10 is a plan view schematically showing the photovoltaic cell device 100 according to modified example 2 of embodiment 2.

FIG. 11 is a cross-sectional view of the photovoltaic cell device 100 according to modified example 3 of embodiment 2.

FIG. 12 is a cross-sectional view of the photovoltaic cell device 100 according to modified example 4 of embodiment 2.

### DETAILED DESCRIPTION

In general, according to one embodiment, a photovoltaic cell device comprises a first optical waveguide comprising a first main surface, a second main surface facing the first main surface, and a first side surface, an optical element facing the second main surface, comprising a cholesteric liquid crystal, and reflecting at least part of light incident on the first main surface toward the first optical waveguide, and a first photovoltaic cell facing the first side surface. The first photovoltaic cell is attached to the first side surface by a transparent first adhesive layer.

Each embodiment can provide a photovoltaic cell device whose size can be increased at low cost.

Embodiments will be described hereinafter with reference to the accompanying drawings. The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the Z-axis is referred to as a first direction A1. A direction parallel to the Y-axis is referred to as a second direction A2. A direction parallel to the X-axis is referred to as a third direction A3. The first direction A1, the second direction A2 and the third direction A3 are orthogonal to each other. The plane defined by the X-axis and the Y-axis is referred to as an X-Y plane. The plane defined by the X-axis and the Z-axis is referred to as an X-Z plane. The plane defined by the Y-axis and the Z-axis is referred to as a Y-Z plane.

### Embodiment 1

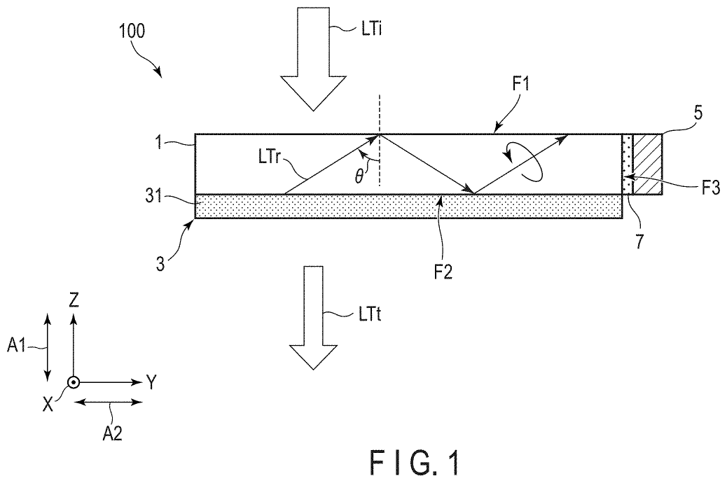

FIG. 1 is a cross-sectional view schematically showing a photovoltaic cell device 100 according to embodiment 1. The photovoltaic cell device 100 comprises an optical waveguide 1, an optical element 3, a photovoltaic cell 5 and an adhesive layer (first adhesive layer) 7.

The optical waveguide 1 consists of a transparent member which transmits light, for example, a transparent glass plate or a transparent synthetic resinous plate. For example, the optical waveguide 1 may consist of a transparent synthetic resinous plate having flexibility. The optical waveguide 1 could have an arbitrary shape. For example, the optical waveguide 1 may be curved. For example, the refractive index of the optical waveguide 1 is greater than that of air. The optical waveguide 1 functions as, for example, window glass.

In this specification, light includes visible light and invisible light. For example, the wavelength of the lower limit of a visible light range is greater than or equal to 360 nm but less than or equal to 400 nm. The wavelength of the upper limit of a visible light range is greater than or equal to 760 nm but less than or equal to 830 nm. Visible light includes the first component (blue component) of a first wavelength range (for example, 400 to 500 nm), the second component (green component) of a second wavelength range (for example, 500 to 600 nm), and the third component (red component) of a third wavelength range (for example, 600 to 700 nm). Invisible light includes ultraviolet light having a wavelength range in which the wavelength is shorter than the first wavelength range, and infrared light having a wavelength range in which the wavelength is longer than the third wavelength range.

In this specification, the term “transparent” should preferably mean “colorless and transparent”. However, the term “transparent” may mean “semitransparent” or “colored and transparent”.

The optical waveguide 1 is shaped like a flat plate parallel to an X-Y plane and comprises a first main surface F1, a second main surface F2 and an external side surface F3. The first main surface F1 and the second main surface F2 are surfaces substantially parallel to the X-Y plane and face each other in a first direction A1. The external side surface F3 is a surface extending in the first direction A1. In the example shown in FIG. 1, the external side surface F3 is a surface substantially parallel to an X-Z plane. The external side surface F3 includes a surface substantially parallel to a Y-Z plane.

The optical element 3 faces the second main surface F2 of the optical waveguide 1 in the first direction A1. The optical element 3 reflects at least part of the light LTi which entered the first main surface F1 toward the optical waveguide 1. For example, the optical element 3 comprises a liquid crystal layer 31 which reflects, of the incident light LTi, at least one of first circularly polarized light and second circularly polarized light which rotates in the opposite direction of the first circularly polarized light. The first circularly polarized light and the second circularly polarized light may be visible light including the first, second and third components described above or may be invisible light. In this specification, reflection in the optical element 3 is accompanied by diffraction inside the optical element 3.

It should be noted that, for example, the optical element 3 may have flexibility. Further, the optical element 3 may be in contact with the second main surface F2 of the optical waveguide 1. Alternatively, a transparent layer such as an adhesive layer may be interposed between the optical element 3 and the optical waveguide 1. It is preferable that the refractive index of the layer interposed between the optical element 3 and the optical waveguide 1 should be substantially equal to that of the optical waveguide 1. The optical element 3 is configured as, for example, a film.

The photovoltaic cell 5 faces the external side surface F3 of the optical waveguide 1 in a second direction A2. The photovoltaic cell 5 receives light and converts the energy of the received light into electricity. Thus, the photovoltaic cell 5 generates electricity by the received light. The type of the photovoltaic cell is not particularly limited. The photovoltaic cell 5 is, for example, a silicon-based photovoltaic cell, a compound-based photovoltaic cell, an organic photovoltaic cell, a perovskite photovoltaic cell or a quantum dot photovoltaic cell. The silicon-based photovoltaic cell includes a photovoltaic cell comprising amorphous silicon, a photovoltaic cell comprising polycrystalline silicon, etc.

The adhesive layer 7 is transparent and attaches the photovoltaic cell 5 to the external side surface F3. The refractive index of the adhesive layer 7 is substantially equal to that of the optical waveguide 1. Here, the phrase “substantially equal to” means that the difference between the refractive index of the adhesive layer 7 and the refractive index of the optical waveguide 1 is less than or equal to 0.1 in the wavelength of causing reflection and diffraction, and should be preferably less than or equal to 0.05.

Now, in the embodiment 1 shown in FIG. 1, the operation of the photovoltaic cell device 100 is explained.

The light LTi incident on the first main surface F1 of the optical waveguide 1 is, for example, solar light.

In the example of FIG. 1, in order to facilitate understanding, light LTi is assumed to enter the optical waveguide 1 so as to be substantially perpendicular to the optical waveguide 1. It should be noted that the incident angle of light LTi with respect to the optical waveguide 1 is not particularly limited. For example, light LTi may enter the optical waveguide 1 at a plurality of incident angles different from each other.

Light LTi proceeds into the optical waveguide 1 through the first main surface F1 and enters the optical element 3 via the second main surface F2. The optical element 3 reflects light LTr which is part of light LTi toward the optical waveguide 1 and the photovoltaic cell 5 and transmits the other light LTt. Here, a light loss such as absorption in the optical waveguide 1 and the optical element 3 is ignored. The light LTr reflected on the optical element 3 is equivalent to the first circularly polarized light having a predetermined wavelength. The light LTr which passes through the optical element 3 includes the second circularly polarized light having a predetermined wavelength and light having a wavelength different from the predetermined wavelength. In this specification, circularly polarized light may be strict circularly polarized light or may be circularly polarized light which approximates elliptically polarized light.

The optical element 3 reflects the first circularly polarized light toward the optical waveguide 1 at an entering angle θ which satisfies the optical waveguide conditions in the optical waveguide 1. Here, the entering angle θ is equivalent to an angle greater than or equal to a critical angle θc which causes total reflection inside the optical waveguide 1. The entering angle θ indicates an angle with respect to a perpendicular line orthogonal to the optical waveguide 1.

Light LTr proceeds into the optical waveguide 1 through the second main surface F2 and propagates inside the optical waveguide 1 while repeating reflection in the optical waveguide 1.

The photovoltaic cell 5 receives the light LTr emitted from the external side surface F3 and generates electricity.

The photovoltaic cell 5 is required to efficiently use the received light for electric generation. For example, in the silicon-based photovoltaic cell 5, if an antireflective film is formed or an antireflective structure is formed on a silicon surface as a technique of preventing light reflection on a silicon surface, the cost may be increased.

In embodiment 1, the photovoltaic cell 5 is attached to the external side surface F3 of the optical waveguide 1 by the transparent adhesive layer 7, and receives the light reflected on the optical element 3 via the optical waveguide 1. When the optical element 3 reflects light toward the optical waveguide 1, the optical element 3 can control the direction of the reflection by the helical structures 311 described later. Thus, the incident angle of light on the photovoltaic cell device 5 can be controlled in the optical waveguide 1, thereby preventing reflection on a silicon surface.

Further, in embodiment 1, the photovoltaic cell 5 is attached to the external side surface F3 of the optical waveguide 1 by the transparent adhesive layer 7. The refractive index of the adhesive layer 7 is substantially equal to that of the optical waveguide 1. Thus, even if light is reflected on the photovoltaic cell device 5, the light can be guided to the optical waveguide 1 again with a very little loss and can be reused for electric generation. In other words, the adhesive layer 7 secures the photovoltaic cell 5 to the optical waveguide 1 and forms an optical path in which the loss is low between the optical waveguide 1 and the photovoltaic cell 5.

Thus, compared to a case where a technique of forming an antireflective film or forming an antireflective structure is applied, an additional component for securing the photovoltaic cell 5 to the optical waveguide 1 is not needed. In this way, the photovoltaic cell device 100 in which the loss is low can be provided at low cost.

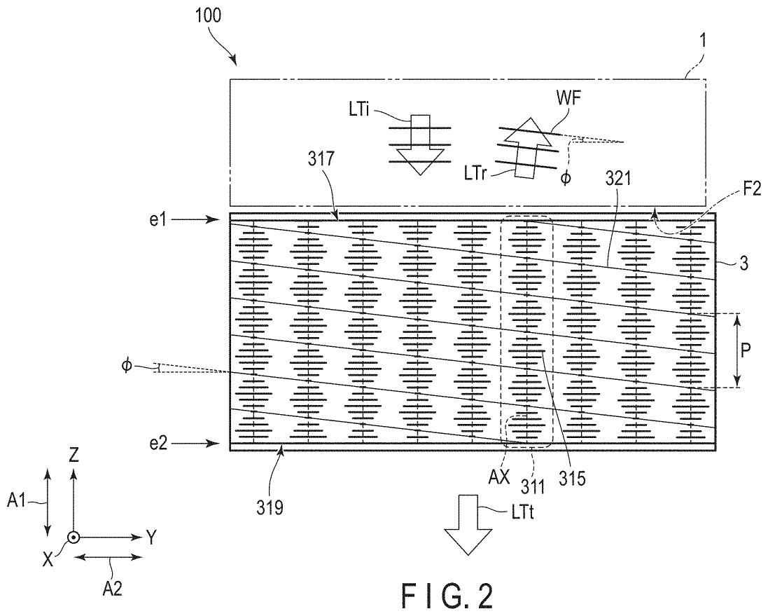

FIG. 2 is a cross-sectional view schematically showing the structure of the optical element 3. The optical waveguide 1 is shown by alternate long and two short dashes lines.

The optical element 3 comprises a plurality of helical structures 311. Each of the helical structures 311 extends in the first direction A1. In other words, the helical axis AX of each of the helical structures 311 is substantially perpendicular to the second main surface F2 of the optical waveguide 1. The helical axis AX is substantially parallel to the first direction A1. Each of the helical structures 311 has a helical pitch P. The helical pitch P indicates one pitch (360 degrees) of the helix. Each of the helical structures 311 includes a plurality of elements 315. The elements 315 are helically stacked in the first direction A1 while twisting.

The optical element 3 comprises a first interface 317 facing the second main surface F2, a second interface 319 on the opposite side of the first interface 317, and a plurality of reflective surfaces 321 between the first interface 317 and the second interface 319. The light LTi emitted from the second main surface F2 after passing through the optical waveguide 1 enters the first interface 317. Each of the first interface 317 and the second interface 319 is substantially perpendicular to the helical axis AX of each helical structure 311. Each of the first interface 317 and the second interface 319 is substantially parallel to the optical waveguide 1 (or the second main surface F2).

The first interface 317 includes the element 315 which is located in an end portion e1 of the both end portions of each helical structure 311. The first interface 317 is located in the boundary between the optical waveguide 1 and the optical element 3. The second interface 319 includes the element 315 which is located in the other end portion e2 of the both end portions of each helical structure 311. The second interface 319 is located in the boundary between the optical element 3 and an air layer.

In embodiment 1, the reflective surfaces 321 are substantially parallel to each other. Each reflective surface 321 inclines with respect to the first interface 317 and the optical waveguide 1 (or the second main surface F2) and has substantially a plane shape extending in a certain direction. Each reflective surface 321 applies selective reflection to light LTr of the light LTi which entered the first interface 317 in accordance with the Bragg's law. Specifically, each reflective surface 321 reflects light LTr such that the wavefront WF of light LTr is substantially parallel to the reflective surface 321. More specifically, each reflective surface 321 reflects light LTr based on the inclination angle φ of the reflective surface 321 with respect to the first interface 317.

The reflective surfaces 321 can be defined as follows. The refractive index sensed by the light (for example, circularly polarized light) which is selectively reflected in the optical element 3 and has a predetermined wavelength gradually changes as the light travels inside the optical element 3. Thus, the Fresnel reflection gradually occurs in the optical element 3. In the helical structures 311, a position at which the change in the refractive index sensed by light is the largest exhibits the strongest Fresnel reflection. In other words, each reflective surface 321 is equivalent to a surface which exhibits the strongest Fresnel reflection in the optical element 3.

Of the helical structures 311, the alignment directions of the elements 315 of the helical structures 311 which are adjacent to each other in the second direction A2 are different from each other. Further, of the helical structures 311, the spacial phases of the helical structures 311 which are adjacent to each other in the second direction A2 are different from each other. Each reflective surface 321 is equivalent to a surface in which the alignment directions of the elements 315 are uniform, or a surface in which spacial phases are uniform. In other words, each of the reflective surfaces 321 inclines with respect to the first interface 317 or the optical waveguide 1.

It should be noted that the shape of each reflective surface 321 is not limited to the plane shape shown in FIG. 2, and may be a curved shape such as a concave shape or a convex shape, and thus, is not particularly limited. Part of each reflective surface 321 may be uneven. The inclination angles φ of the reflective surfaces 321 may not be uniform. The reflective surfaces 321 may not be regularly aligned. The reflective surfaces 321 may be configured to have arbitrary shapes based on the distribution of the spacial phases of the helical structures 311.

In the present embodiment, the helical structures 311 are cholesteric liquid crystals. Each of the elements 315 is equivalent to a liquid crystal molecule. In FIG. 2, in order to simplify the figure, each element 315 represents a liquid crystal molecule which faces an average alignment direction as a representative of the liquid crystal molecules located in the X-Y plane.

Cholesteric liquid crystals which are the helical structures 311 reflect circularly polarized light which is light having a predetermined wavelength λ included in a selective reflection range Δλ and which rotates in the same rotation direction as the twist directions of the helices of the cholesteric liquid crystals. For example, when the twist direction of the cholesteric liquid crystal is right-handed, of the light having the predetermined wavelength A, the cholesteric liquid crystal reflects right-handed circularly polarized light and transmits left-handed circularly polarized light. Similarly, when the twist direction of the cholesteric liquid crystal is left-handed, of the light having the predetermined wavelength λ, the cholesteric liquid crystal reflects left-handed circularly polarized light and transmits right-handed circularly polarized light.

When the pitch of the helix of cholesteric liquid crystals is defined as P, and the refractive index of liquid crystal molecules with respect to extraordinary light is defined as ne, and the refractive index of liquid crystal molecules with respect to ordinary light is defined as no, in general, the selective reflection range Δλ of cholesteric liquid crystals with respect to normal incident light is shown by “no*P to ne*P”. Specifically, the selective reflection range Δλ of cholesteric liquid crystals changes based on the inclination angle φ of the reflective surfaces 321, the incident angle on the first interface 317, etc., with respect to the range “no*P to ne*P”.

When the optical element 3 consists of cholesteric liquid crystals, for example, the optical element 3 is formed as a film. The optical element 3 as a film is formed by, for example, polymerizing a plurality of helical structures 311. Specifically, the optical element 3 as a film is formed by polymerizing the elements (liquid crystal molecules) 315 contained in the optical element 3. For example, a plurality of liquid crystal molecules are polymerized by emitting light to the liquid crystal molecules.

Alternatively, the optical element 3 as a film is formed by, for example, controlling the alignment of polymer liquid crystal materials showing a liquid crystalline state at a predetermined temperature or a predetermined concentration so as to form a plurality of helical structures 311 in a liquid crystalline state and subsequently causing them to transition to a solid while maintaining the alignment.

By polymerization or transition to a solid, in the optical element 3 as a film, adjacent helical structures 311 are bound together while maintaining the alignment of the helical structures 311, in other words, while maintaining the spacial phases of the helical structures 311. As a result, in the optical element 3 as a film, the alignment direction of each liquid crystal molecule is fixed.

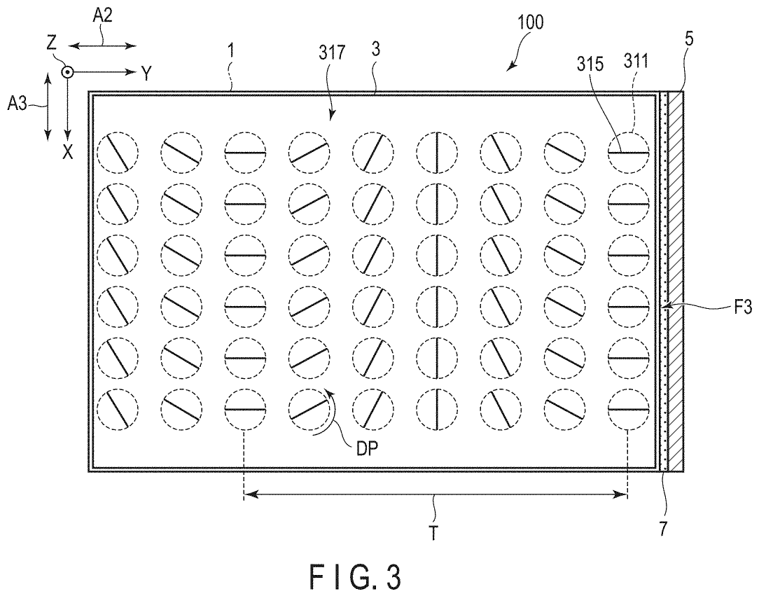

FIG. 3 is a plan view schematically showing the photovoltaic cell device 100.

FIG. 3 shows an example of the spacial phases of the helical structures 311. Here, the spacial phases are shown as the alignment directions of, of the elements 315 contained in the helical structures 311, the elements 315 located at the first interface 317.

Regarding the helical structures 311 arranged in the second direction A2, the alignment directions of the elements 315 located at the first interface 317 are different from each other. In other words, the spacial phases of the helical structures 311 at the first interface 317 differ in the second direction A2.

To the contrary, regarding the helical structures 311 arranged in a third direction A3, the alignment directions of the elements 315 located at the first interface 317 are substantially coincident with each other. In other words, the spacial phases of the helical structures 311 at the first interface 317 are substantially coincident with each other in the third direction A3.

In particular, regarding the helical structures 311 arranged in the second direction A2, the alignment direction varies with each element 315 by a certain degree. In other words, at the first interface 317, the alignment direction linearly varies with the elements 315 arranged in the second direction A2. Thus, the spacial phase linearly varies in the second direction A2 with the helical structures 311 arranged in the second direction A2. As a result, like the optical element 3 shown in FIG. 2, the reflective surfaces 321 which incline with respect to the first interface 317 and the optical waveguide 1 are formed. Here, the phrase “linearly vary” means that, for example, the amount of variation in the alignment directions of the elements 315 is shown by a linear function.

Here, as shown in FIG. 3, the interval between two helical structures 311 when the alignment directions of the elements 315 vary by 180 degrees in the second direction A2 at the first interface 317 is defined as pitch T of the helical structures 311. In FIG. 3, DP indicates the twist direction of each element. The inclination angle φ of each reflective surface 321 shown in FIG. 2 is arbitrarily set based on pitch T and the helical pitch P.

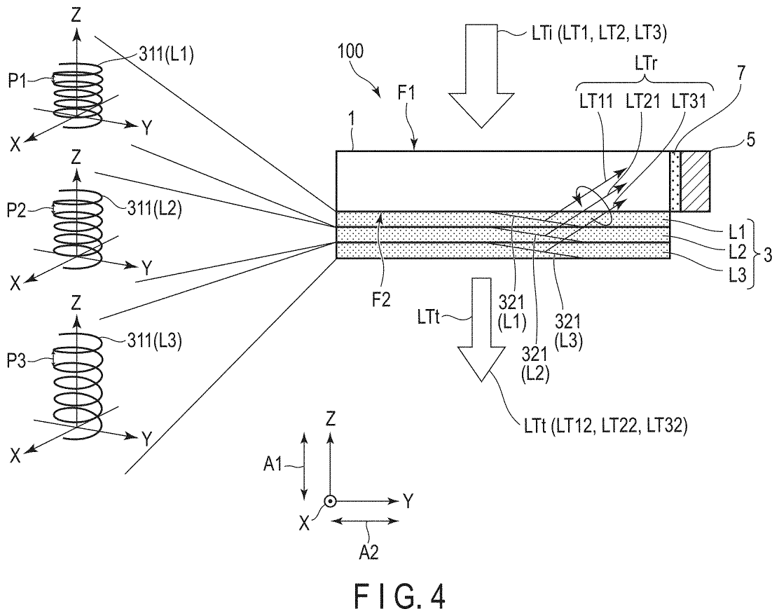

FIG. 4 is a cross-sectional view schematically showing an example of the optical element 3. In the example shown in FIG. 4, the optical element 3 comprises a first layer L1 which mainly reflects the first component LT1, a second layer L2 which mainly reflects the second component LT2 and a third layer L3 which mainly reflects the third component LT3. The first layer L1, the second layer L2 and the third layer L3 are stacked in this order in the first direction A1. The first layer L1 faces the second main surface F2. It should be noted that the order in which the first layer L1, the second layer L2 and the third layer L3 are stacked is not limited to the example shown in FIG. 4.

FIG. 4 shows, as the helical structures 311 in the first layer L1, the second layer L2 and the third layer L3, cholesteric liquid crystals which twist in a single direction are schematically shown. The helical structures 311 in the first layer L1, the second layer L2 and the third layer L3 twist in the same direction, and are configured to reflect, for example, the first circularly polarized light.

In the first layer L1, the helical structure 311 comprises a first helical pitch P1 so as to reflect the first component LT11 of the first circularly polarized light.

In the second layer L2, the helical structure 311 comprises a second helical pitch P2 so as to reflect the second component LT21 of the first circularly polarized light. The second helical pitch P2 is different from the first helical pitch P1.

In the third layer L3, the helical structure 311 comprises a third helical pitch P3 so as to reflect the third component LT31 of the first circularly polarized light. The third helical pitch P3 is different from the first helical pitch P1 and the second helical pitch P2.

The second helical pitch P2 is greater than the first helical pitch P1, and the third helical pitch P3 is greater than the second helical pitch P2 (P1<P2<P3).

Here, this specification explains a case where the incident light LTi which passed through the optical waveguide 1 includes the first component LT1, the second component LT2 and the third component LT3.

On the reflective surface 321 of the first layer L1, the first component LT11 of the first circularly polarized light is reflected. In addition to the first component LT12 of the second circularly polarized light, the second component LT2 and the third component LT3 pass through the reflective surface 321 of the first layer L1.

On the reflective surface 321 of the second layer L2, the second component LT21 of the first circularly polarized light is reflected. In addition to the first and second components LT12 and LT22 of the second circularly polarized light, the third component LT3 passes through the reflective surface 321 of the second layer L2.

On the reflective surface 321 of the third layer L3, the third component LT31 of the first circularly polarized light is reflected. The first, second and third components LT12, LT22 and LT32 of the second circularly polarized light pass through the reflective surface 321 of the third layer L3.

Thus, the light LTr reflected on the optical element 3 includes the first, second and third components LT11, LT21 and LT31 of the first circularly polarized light. The light LTt which passes through the optical element 3 includes the first, second and third components LT12, LT22 and LT32 of the second circularly polarized light.

It should be noted that the helical structures 311 of one of the layers may twist in a direction different from the helical structures 311 of the other layers. In this case, circularly polarized light rays in opposite directions are reflected.

In the example shown in FIG. 4, the first layer L1, the second layer L2 and the third layer L3 are individually formed. In the first layer L1, the first helical pitch P1 of the helical structures 311 undergoes very little change and is constant. Similarly, in the second layer L2, the second helical pitch P2 is almost constant, and further, in the third layer L3, the third helical pitch P3 is almost constant.

It should be noted that the optical element 3 may be a liquid crystal layer of a single-layer body, and the helical pitch P may continuously change in the first direction A1.

The optical element 3 may include a layer which reflects invisible light.

### Modified Example 1

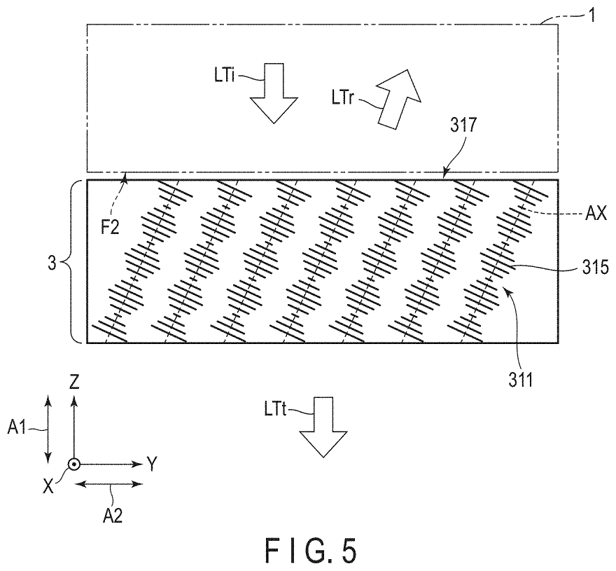

FIG. 5 is a cross-sectional view schematically showing the optical element 3 according to modified example 1 of embodiment 1.

The modified example 1 shown in FIG. 5 is different from the above embodiment 1 in respect that the helical axis AX of each helical structure 311 inclines with respect to the optical waveguide 1 or the second main surface F2. In modified example 1 here, the spacial phases of the helical structures 311 at the first interface 317 or the X-Y plane are substantially coincident with each other. The other properties of the helical structures 311 of modified example 1 are the same as the helical structures 311 of the embodiment 1 described above.

In this modified example 1, the optical element 3 reflects light LTr which is part of the incident light LTi which passed through the optical waveguide 1 at a reflective angle based on the inclination of the helical axis AX, and transmits the other light LTt.

In this modified example 1, effects similar to those of the above embodiment 1 are obtained.

### Modified Example 2

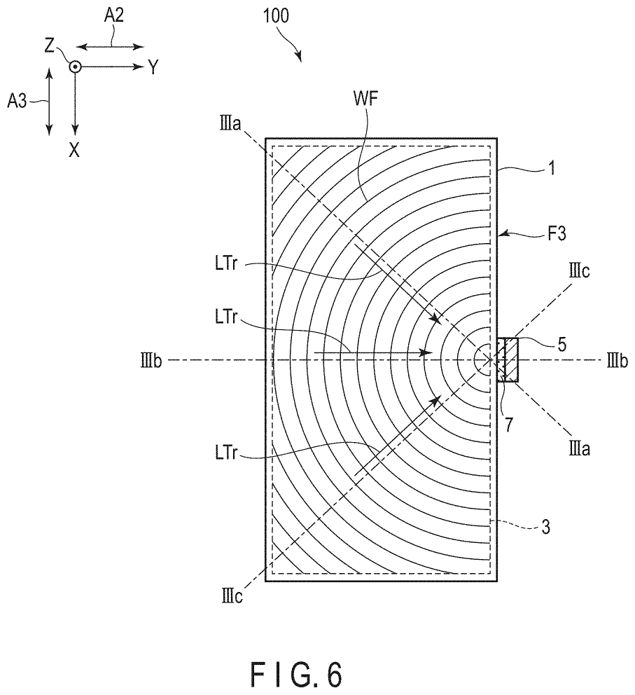

FIG. 6 is a plan view schematically showing the photovoltaic cell device 100 according to modified example 2. Modified example 2 is different from the above embodiment and modified example 1 in respect that the optical element 3 is configured to condense light toward the photovoltaic cell device 5. In order to facilitate understanding of propagation of the light LTr reflected on the optical element 3, FIG. 6 shows the wavefronts WF of light LTr.

In FIG. 6, the section of the photovoltaic cell device 100 along the IIIa-IIIa line, the section of the photovoltaic cell device 100 along the IIIb-IIIb line and the section of the photovoltaic cell device 100 along the IIIc-IIIc line are similar to the section of the photovoltaic cell device 100 shown in FIG. 1.

The section of the optical element 3 along the IIIa-IIIa line, the section of the optical element 3 along the IIIb-IIIb line and the section of the optical element 3 along the IIIc-IIIc line are similar to, for example, the section of the optical element 3 shown in FIG. 2 or the section of the optical element 3 shown in FIG. 5.

In other words, as explained with reference to FIG. 2 or FIG. 5, the reflective surfaces 321 of the optical element 3 incline so as to reflect light toward the photovoltaic cell 5 at respective positions in the X-Y plane. The light LTr reflected on the optical element 3 propagates through the optical waveguide 1 toward the photovoltaic cell 5.

In this modified example 2, effects similar to those of the above embodiment 1 are obtained.

Further, in modified example 2, the optical element 3 comprises the reflective surfaces 321 which incline so as to condense light toward the photovoltaic cell 5, and the reflected light LTr propagates toward the photovoltaic cell 5 in the optical waveguide 1. Thus, the amount of light received in the photovoltaic cell 5 per unit time can be increased. This configuration can reduce the size of the photovoltaic cell 5 and increase the electricity generated in the photovoltaic cell 5.

### Embodiment 2

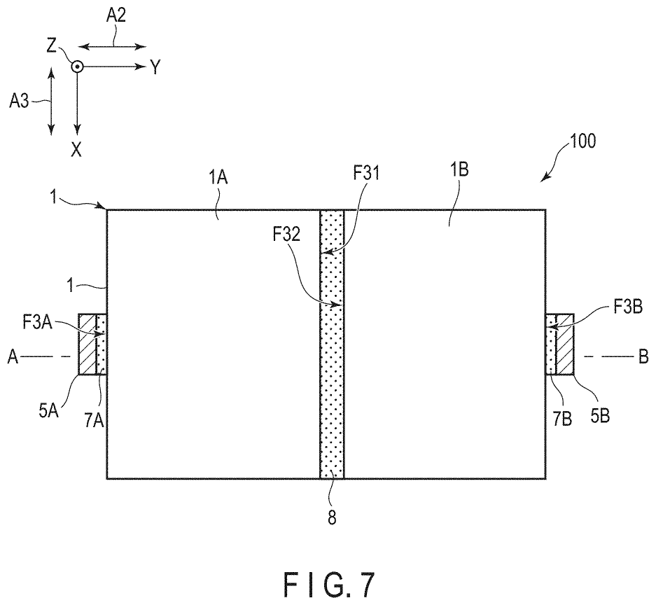

FIG. 7 is a plan view schematically showing a photovoltaic cell device 100 according to embodiment 2. Here, the illustration of an optical element 3 is omitted. Embodiment 2 is different from embodiment 1 in respect that the photovoltaic cell device 100 is configured by attaching a plurality of optical waveguides 1 arranged in a second direction A2. In the example shown in FIG. 7, the photovoltaic cell device 100 comprises, as the optical waveguides 1, an optical waveguide (first optical waveguide) 1A and an optical waveguide (second optical waveguide) 1B. The optical waveguide 1A and the optical waveguide 1B are attached to each other by an adhesive layer (second adhesive layer) 8. The optical waveguide 1A and the optical waveguide 1B are arranged in the second direction A2. However, they may be arranged in a third direction A3.

Each of the optical waveguide 1A and the optical waveguide 1B is shaped like a flat plate parallel to an X-Y plane. The optical waveguide 1A and the optical waveguide 1B are formed of the same transparent material and have the same refractive index.

The optical waveguide 1A comprises an external side surface (first side surface) F3A and a side surface (second side surface) F31 different from the external side surface F3A. The optical waveguide 1B comprises an external side surface F3B and a side surface (third side surface) F32 different from the external side surface (fourth side surface) F3B. The side surface F31 and the side surface F32 are surfaces extending in the third direction A3. The side surface F31 faces the side surface F32 in the second direction A2.

The adhesive layer 8 is transparent and attaches the optical waveguide 1A to the optical waveguide 1B between the side surface F31 and the side surface F32. The refractive index of the adhesive layer 8 is substantially equal to that of the optical waveguide 1A and the optical waveguide 1B. For example, the difference between the refractive index of the adhesive layer 8 and the refractive index of the optical waveguide 1A and the difference between the refractive index of the adhesive layer 8 and the refractive index of the optical waveguide 1B are less than or equal to 0.1 in the wavelength of causing reflection and diffraction, and should be preferably less than or equal to 0.05.

The photovoltaic cell device 100 shown in FIG. 7 comprises a plurality of photovoltaic cells 5A and 5B. The photovoltaic cell (first photovoltaic cell) 5A is attached to the external side surface F3A of the optical waveguide 1A by an adhesive layer 7A. The photovoltaic cell (second photovoltaic cell) 5B is attached to the external side surface F3B of the optical waveguide 1B by an adhesive layer 7B. The refractive indices of the adhesive layers 7A and 7B are equal to the refractive index of the adhesive layer 8. For example, the adhesive layers 7A and 7B are formed of the same material as the adhesive layer 8. It should be noted that the adhesive layers 7A and 7B and the adhesive layer 8 may be formed of different materials as long as the materials are transparent and have substantially the same refractive index.

The photovoltaic cell device 100 may comprise only one of the photovoltaic cells 5A and 5B or may comprise three or more photovoltaic cells 5.

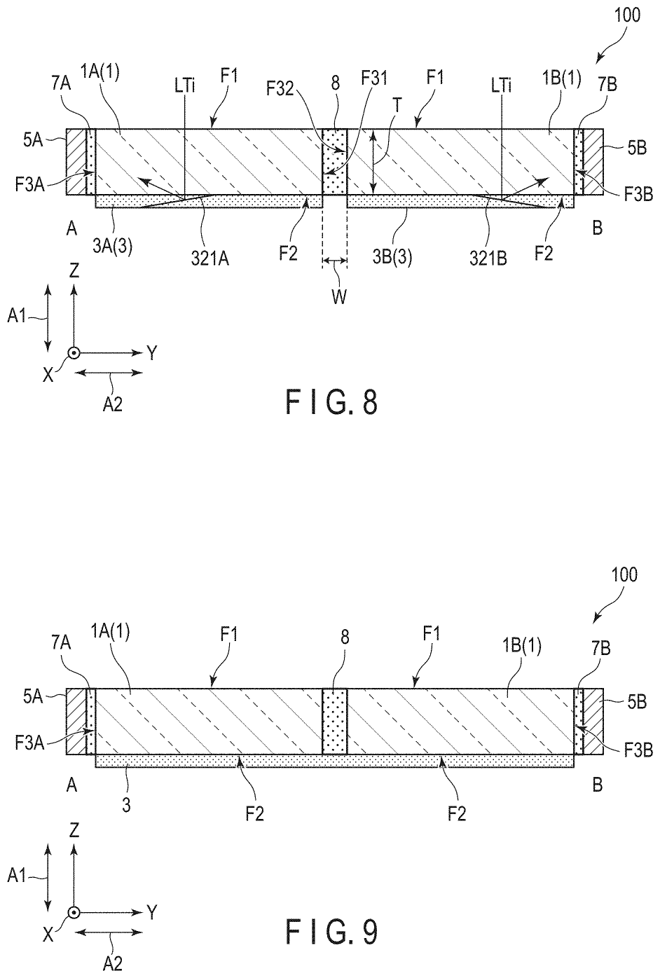

FIG. 8 is a cross-sectional view of the photovoltaic cell device 100 along the A-B line of FIG. 7. The adhesive layer 8 has thickness T equal to the thicknesses of the optical waveguides 1A and 1B and has width W equal to the interval between the side surface F31 and the side surface F32. Thickness T is greater than width W (T>W). Thickness T is the length in a first direction A1. Width W is the length in the second direction A2. The adhesive layer 8 forms part of a first main surface F1 and part of a second main surface F2. In other words, each of the first main surface F1 and the second main surface F2 is a surface formed by the optical waveguide 1A, the optical waveguide 1B and the adhesive layer 8.

The optical element 3 comprises a first element 3A facing the optical waveguide 1A, and a second element 3B facing the optical waveguide 1B. The first element 3A is spaced apart from the second element 3B. In the example shown in FIG. 8, neither the first element 3A nor the second element 3B is provided at a position facing the adhesive layer 8 in the first direction A1.

The reflective surface 321A of the first element 3A is an inclined surface different from the reflective surface 321B of the second element 3B. In other words, the reflective surface 321A inclines so as to reflect the incident light LTi which passed through the optical waveguide 1 toward the photovoltaic cell 5A. The reflective surface 321B inclines so as to reflect the incident light LTi which passed through the optical waveguide 1 toward the photovoltaic cell 5B.

In this embodiment 2, effects similar to those of the above embodiment 1 are obtained. In addition, as a plurality of optical waveguides 1 are attached, a large photovoltaic cell device 100 can be easily provided.

Further, as the adhesive layer 8 which attaches the optical waveguide 1A to the optical waveguide 1B has the same refractive index as each optical waveguide, the adhesive layer 8 forms an optical path in which the loss is low between the optical waveguide 1A and the optical waveguide 1B. In this configuration, for example, the light which propagates inside the optical waveguide 1A can be transmitted to the adhesive layer 8 and the optical waveguide 1B, and further, the light which propagates inside the optical waveguide 1B can be transmitted to the adhesive layer 8 and the optical waveguide 1A.

Moreover, since thickness T is greater than width W in the adhesive layer 8, even if the optical element 3 facing the adhesive layer 8 is not provided, light leakage in the adhesive layer 8 is prevented.

In embodiment 2, the explanation of the details of the optical element 3 is omitted. However, as explained with reference to FIG. 2 in embodiment 1, the inclined reflective surfaces 321A and 321B may be formed by adjusting the spacial phase. Alternatively, as explained with reference to FIG. 5, the inclined reflective surfaces 321A and 321B may be formed by inclining the helical axis AX.

### Modified Example 1

FIG. 9 is a cross-sectional view of the photovoltaic cell device 100 according to modified example 1 of embodiment 2.

The modified example 1 shown in FIG. 9 is different from the embodiment 2 shown in FIG. 8 in respect that the optical element 3 faces the optical waveguide 1A and the optical waveguide 1B across the adhesive layer 8. In other words, the optical element 3 is formed as a single sheet and is provided over substantially the entire second main surface F2.

In this modified example 1, effects similar to those of the above embodiment 2 are obtained. In addition, the number of components can be reduced.

### Modified Example 2

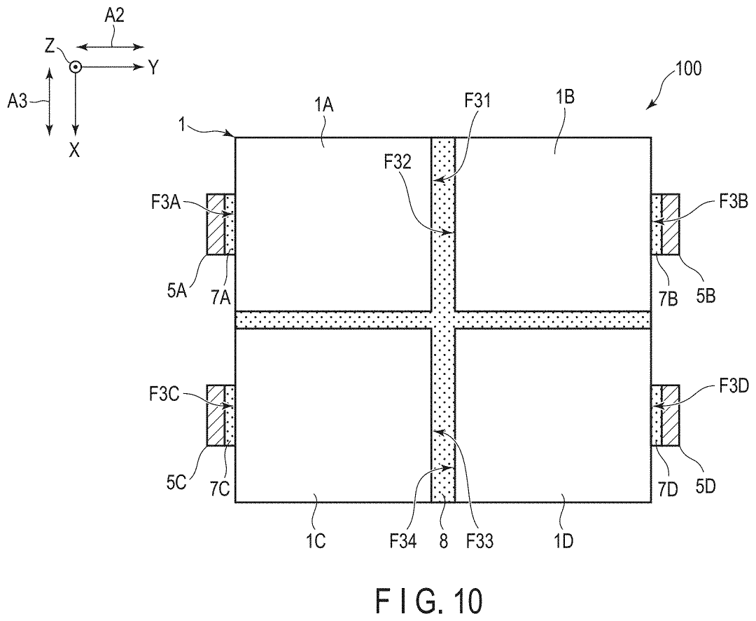

FIG. 10 is a plan view schematically showing the photovoltaic cell device 100 according to modified example 2 of embodiment 2. Here, the illustration of the optical element 3 is omitted. The modified example 2 shown in FIG. 10 is different from the embodiment 2 shown in FIG. 7 in respect that a plurality of optical waveguides arranged in the second direction A2 and the third direction A3 are attached.

The photovoltaic cell device 100 comprises the optical waveguide 1A, the optical waveguide 1B, an optical waveguide 1C, an optical waveguide 1D and the adhesive layer (second adhesive layer) 8. The optical waveguide 1A and the optical waveguide 1B are arranged in the second direction A2. The optical waveguide 1C and the optical waveguide 1D are arranged in the second direction A2. The optical waveguide 1A and the optical waveguide 1C are arranged in the third direction A3. The optical waveguide 1B and the optical waveguide 1D are arranged in the third direction A3.

Each of the optical waveguide 1A, the optical waveguide 1B, the optical waveguide 1C and the optical waveguide 1D is shaped like a flat plate parallel to the X-Y plane. The optical waveguide 1A, the optical waveguide 1B, the optical waveguide 1C and the optical waveguide 1D are formed of the same transparent material and have the same refractive index.

The optical waveguide 1A comprises the side surface F31 different from the external side surface F3A. The optical waveguide 1B comprises the side surface F32 different from the external side surface F3B. The optical waveguide 1C comprises a side surface F33 different from an external side surface F3C. The optical waveguide 1D comprises a side surface F34 different from an external side surface F3D. The side surface F31, the side surface F32, the side surface F33 and the side surface F34 are surfaces having an L-shape in the X-Y plane.

The adhesive layer 8 is transparent and attaches the optical waveguide 1A, the optical waveguide 1B, the optical waveguide 1C and the optical waveguide 1D to each other in the side surface F31, the side surface F32, the side surface F33 and the side surface F34. The refractive index of the adhesive layer 8 is substantially equal to that of the optical waveguide 1A, etc.

The photovoltaic cell 5A is attached to the external side surface F3A of the optical waveguide 1A by the adhesive layer 7A. The photovoltaic cell 5B is attached to the external side surface F3B of the optical waveguide 1B by the adhesive layer 7B. A photovoltaic cell 5C is attached to the external side surface F3C of the optical waveguide 1C by an adhesive layer 7C. A photovoltaic cell 5D is attached to the external side surface F3D of the optical waveguide 1D by an adhesive layer 7D.

In this modified example 2, effects similar to those of the above embodiment 2 are obtained.

### Modified Example 3

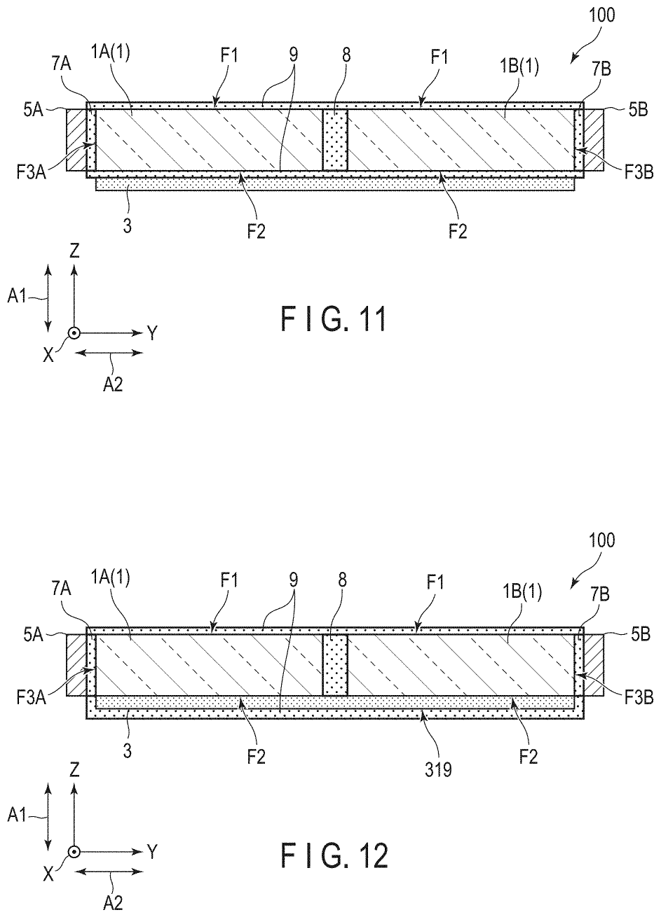

FIG. 11 is a cross-sectional view of the photovoltaic cell device 100 according to modified example 3 of embodiment 2.

The modified example 3 shown in FIG. 11 is different from the above embodiment 2 in respect that the photovoltaic cell device 100 further comprises a transparent protective layer 9 which covers the optical waveguide 1A and the optical waveguide 1B. The protective layer 9 covers substantially the entire first main surface F1 and the entire second main surface F2. In other words, the protective layer 9 is in contact with the first main surface F1 and the second main surface F2. The protective layer 9 is also in contact with the adhesive layer 8. On the second main surface F2 side of the optical waveguide 1A and the optical waveguide 1B, the protective layer 9 is provided between the optical waveguide 1A and the optical element 3 and between the optical waveguide 1B and the optical element 3.

The protective layer 9 is formed of, for example, the same material as the adhesive layer 8. The refractive index of the protective layer 9 is substantially equal to that of the optical waveguide 1 (or the refractive indices of the optical waveguide 1A and the optical waveguide 1B).

In this modified example 3, effects similar to those of the above embodiment 2 are obtained. In addition, the damage to the optical waveguide 1 can be prevented.

### Modified Example 4

FIG. 12 is a cross-sectional view of the photovoltaic cell device 100 according to modified example 4 of embodiment 2.

The modified example 4 shown in FIG. 12 is different from the modified example 3 shown in FIG. 11 in respect that the transparent protective layer 9 covers the optical waveguide 1A, the optical waveguide 1B and the optical element 3. The protective layer 9 covers substantially the entire surface of each of the first main surface F1 and the optical element 3. On the second main surface F2 side of the optical waveguide 1A and the optical waveguide 1B, the optical element 3 is provided between the optical waveguide 1A and the protective layer 9 and between the optical waveguide 1B and the protective layer 9. In other words, the protective layer 9 is in contact with each of the first main surface F1 and the second interface 319 of the optical element 3.

In this modified example 4, effects similar to those of the above modified example 3 are obtained.

It should be noted that, in modified example 3 and modified example 4, the optical element 3 may comprise the first and second elements 3A and 3B spaced apart from each other as shown in FIG. 8, or may be formed as a single sheet as shown in FIG. 9.

The protective layer 9 may further cover the external side surfaces F3A and F3B. In this case, the protective layer 9 may be replaced by the adhesive layers 7A and 7B. In other words, the photovoltaic cells 5A and 5B may be attached by the protective layer 9. The protective layer 9 and the adhesive layer 7A may be interposed between the photovoltaic cell 5A and the external side surface F3A. The protective layer 9 and the adhesive layer 7B may be interposed between the photovoltaic cell 5B and the external side surface F3B.

The embodiments 1 and 2 described above can be combined with each other.

As explained above, the embodiments can provide a photovoltaic cell device in which the loss is low at low cost.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photovoltaic cell device comprising:
a first optical waveguide comprising a first main surface, a second main surface facing the first main surface, and a first side surface;
an optical element facing the second main surface, comprising a cholesteric liquid crystal, and reflecting at least part of light incident on the first main surface toward the first optical waveguide; and
a first photovoltaic cell facing the first side surface, wherein
the first photovoltaic cell is attached to the first side surface by a transparent first adhesive layer.

2. The photovoltaic cell device of claim 1, further comprising a second optical waveguide provided so as to be adjacent to the first optical waveguide, wherein
the first optical waveguide comprises a second side surface different from the first side surface,
the second optical waveguide comprises a third side surface facing the second side surface, and
the first optical waveguide and the second optical waveguide are attached to each other by a transparent second adhesive layer located between the second side surface and the third side surface.

3. The photovoltaic cell device of claim 2, wherein
the second adhesive layer has a thickness equal to thicknesses of the first optical waveguide and the second optical waveguide, and has a width equal to an interval between the second side surface and the third side surface, and
the thickness of the second adhesive layer is greater than the width of the second adhesive layer.

4. The photovoltaic cell device of claim 2, wherein
the optical element comprises a first element facing the first optical waveguide, and a second element facing the second optical waveguide, and
the first element is spaced apart from the second element.

5. The photovoltaic cell device of claim 2, wherein
the optical element faces the first optical waveguide and the second optical waveguide across the second adhesive layer.

6. The photovoltaic cell device of claim 2, wherein
the second optical waveguide comprises a fourth side surface different from the third side surface, and
a second photovoltaic cell is attached to the fourth side surface.

7. The photovoltaic cell device of claim 1, wherein
a refractive index of the first adhesive layer is equal to a refractive index of the first optical waveguide.

8. The photovoltaic cell device of claim 2, wherein
a refractive index of the second adhesive layer is equal to refractive indices of the first optical waveguide and the second optical waveguide.

9. The photovoltaic cell device of claim 2, wherein
a refractive index of the first adhesive layer is equal to a refractive index of the second adhesive layer.

10. The photovoltaic cell device of claim 2, further comprising a transparent protective layer which covers the first optical waveguide and the second optical waveguide, and
a refractive index of the protective layer is equal to refractive indices of the first optical waveguide and the second optical waveguide.

11. The photovoltaic cell device of claim 2, further comprising a transparent protective layer which covers the first optical waveguide, the second optical waveguide and the optical element, and
a refractive index of the protective layer is equal to refractive indices of the first optical waveguide and the second optical waveguide.

12. The photovoltaic cell device of claim 1, wherein
a difference between a refractive index of the first adhesive layer and a refractive index of the first optical waveguide is less than or equal to 0.1.

13. The photovoltaic cell device of claim 2, wherein
a difference between a refractive index of the second adhesive layer and a refractive index of the first optical waveguide and a difference between the refractive index of the second adhesive layer and a refractive index of the second optical waveguide is less than or equal to 0.1.
